(19) United States
(12) Patent Application Publication
(10) Pub. No.: US 2026/0118412 A1
(43) Pub. Date: Apr. 30, 2026

(54) TEMPERATURE CONTROL DEVICE FOR SEMICONDUCTOR PRODUCTS TO CHANGE FLOW PATH OF TEST GAS BASED ON DIFFERENT STATES

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Ki Sung KIM, Ansan-si (KR); Se I Mi CHOI, Anyang-si (KR)

(21) Appl. No.: 19/057,710

(22) Filed: Feb. 19, 2025

(30) Foreign Application Priority Data
Oct. 24, 2024 (KR) 10-2024-0146965

(51) Int. Cl. G01R 31/28

(52) U.S. Cl. CPC G01R 31/2875

(57) ABSTRACT

Disclosed is a temperature control device for a semiconductor product, including: a push unit configured to relatively approach a test tray for carrying the semiconductor product, and including a discharge port formed to discharge the test gas; a duct unit that including a discharge channel formed to deliver the test gas to the discharge port; and a flow path opening/closing unit configured to prevent the test gas from being discharged to the discharge port in an initial state, and to allow the test gas to be discharged to the discharge port in a test state.

### CROSS REFERENCE TO RELATED APPLICATION

Priority to Korean patent application number 10-2024-0146965 filed on Oct. 24, 2024, the entire disclosure of which is incorporated by reference herein, is claimed.

### BACKGROUND OF THE INVENTION

### Field of the Invention

The disclosure relates to a temperature control device for semiconductor products, which changes a flow path of test gas based on different states.

### Description of the Related Art

A high bandwidth memory (HBM) was originated due to a higher memory bandwidth generally required in high-performance applications of a computer and a graphics processing unit. The existing graphics double data rate (GDDR) memory technology has been widely used in high-performance graphics cards and systems, but has reached its limits due to increasing bandwidth requirements. Accordingly, memory manufacturers have demanded new technologies to provide a higher bandwidth and to process data more efficiently.

To meet such a demand, the HBM has adopted an innovative design of forming a memory chip stack. In the HBM, memory chips are stacked vertically to provide advantages of achieving a high bandwidth, taking up less space, and reducing power consumption. These advantages have provided a backdrop for the HBM to attract attention as the memory bandwidth and power efficiency become more import in high-performance computing and graphics processing systems.

Meanwhile, when the efficiency of testing is taken into account, the HBM needs to be tested in a die state before packaging. Because the die of the HBM has many more contact portions than those of the existing memories, the many contact portions are provided at a fine pitch in a limited area.

In this case, the test generally performed for semiconductor products is to determine whether the semiconductor products operate normally while being exposed to a predetermined thermal environment. For example, a test temperature may be set to a high temperature environment of 60 to 200 degrees Celsius, or may be set to a low temperature environment of −60 to 0 degrees Celsius. The high or low temperature environment for the test is significantly different from the room temperature. Therefore, if the temperature is changed with the semiconductor products loaded into a test device, it takes a considerably long time to reach the thermal environment for the test. If the temperature around the test device is controlled in advance, it is possible to shorten the foregoing preparation time, but too much energy is required to maintain the test environment due to continuous heat exchange with the external environment.

### SUMMARY OF THE INVENTION

An aspect of the disclosure is to provide a temperature control device which prepares a test environment in advance while maximizing energy efficiency.

The problems of the disclosure are not limited to the aforementioned problems, and other problems not mentioned above may become apparent to those skilled in the art from the following description.

According to an embodiment of the disclosure, A temperature control device for a semiconductor product, which changes a flow path of test gas based on different states, includes: a push unit configured to relatively approach a test tray for carrying the semiconductor product, and including a discharge port formed to discharge the test gas for controlling a test environment; a duct unit that including a discharge channel formed to deliver the test gas from an outside to the discharge port; and a flow path opening/closing unit configured to prevent the test gas from being discharged to the discharge port by obstructing the test gas flowing through a discharge communication hole located between the discharge port and the discharge channel in an initial state, and to allow the test gas to be discharged to the discharge port in a test state where the push unit relatively approaches the test tray.

The flow path opening/closing unit may include a discharge channel push body placed inside the discharge channel, configured to be in close contact with the discharge communication hole in the initial state, and to be spaced apart from the discharge communication hole in the test state switched by receiving an external force.

The flow path opening/closing unit may further include a discharge channel elastic member configured to provide a restoring force to bring the discharge channel push body into close contact with the discharge communication hole.

The discharge channel may include an accommodating section having one end connected to the discharge communication hole and allowing the discharge channel push body to advance and retreat therein, and an inner section connected to other end of the accommodating section and forming a stepped portion to support the discharge channel elastic member.

The duct unit may further include an exhaust channel formed to exhaust the test gas, and a circulation channel connecting the discharge channel and the exhaust channel.

The push unit may further include an exhaust port to perform fluidic communication with the exhaust channel.

The flow path opening/closing unit may further include an exhaust channel push body placed inside the exhaust channel, configured to be in close contact with an exhaust communication hole located between the exhaust port and the exhaust channel in the initial state, and to be spaced apart from the exhaust communication hole in the test state.

The circulation channel may be exposed to one side of the discharge channel push body in the initial state, and face the discharge channel push body in the test state.

The push unit may include a push pipe configured to form at least a partial section of the discharge port, to be inserted into the duct unit, and to press the discharge channel push body as switched over from the initial state to the test state.

The push pipe may include a gas communication groove formed at a distal end thereof to communicate with the discharge port so that the test gas in the discharge channel can be delivered to the discharge port in the test state.

The discharge channel push body may be formed to have a cross-section larger than the cross-section of the discharge communication hole and smaller than the cross-section of the discharge channel.

The push unit may further include a guide end extending parallel to the push pipe and inserted in the duct unit to guide a moving direction of the push unit.

The push unit may further include a guide end elastic member configured to elastically support the guide end in a direction of bring the push pipe into close contact with the discharge channel push body.

The duct unit may include an auxiliary fluid discharge pipe disposed penetrating the push unit, and allowing an auxiliary fluid different in temperature from the test gas to flow therein.

The temperature control device may further include a temperature measurement sensor adjacent to the discharge port and the exhaust port, and disposed parallel to a virtual line connecting the discharge port and the exhaust port.

Other specific details of the disclosure are included in the detailed description and the accompanying drawings.

### BRIEF DESCRIPTION OF THE DRAWINGS

FIG. 1 is a schematic diagram showing a temperature control system according to an embodiment of the disclosure.

FIG. 2 is a diagram showing a test tray and an insert according to an embodiment of the disclosure.

FIG. 3 is a conceptual diagram showing a temperature control device according to an embodiment of the disclosure.

FIG. 4 is a diagram showing a duct block and multiple push units connected to the duct block according to an embodiment of the disclosure.

FIG. 5 is a diagram showing a portion of a duct block mounted to a distribution plate according to an embodiment of the disclosure.

FIG. 6 is a front perspective view of a push unit according to an embodiment of the disclosure.

FIG. 7 is a rear perspective view of a push unit according to an embodiment of the disclosure.

FIG. 8 is a diagram showing a first duct housing, from which a pushing unit is separated, according to an embodiment of the disclosure.

FIG. 9 is a diagram showing a second duct housing, from which a first duct housing is separated, according to an embodiment of the disclosure.

FIG. 10 is a diagram showing an initial state of a temperature control device according to an embodiment of the disclosure.

FIG. 11 is a diagram showing a test state of a temperature control device according to an embodiment of the disclosure.

FIG. 12 is a diagram for describing flow an expansion groove according to an embodiment of the disclosure.

FIG. 13 is a schematic cross-sectional view of a duct block and a push unit according to another embodiment of the disclosure.

### DETAILED DESCRIPTION OF THE INVENTION

The merits and characteristics of the disclosure and a method for achieving the merits and characteristics will become more apparent from embodiments described below in detail in conjunction with the accompanying drawings. However, the disclosure is not limited to the disclosed embodiments, but may be implemented in various different ways. The embodiments are provided to only complete the disclosure and to allow those skilled in the art to understand the category of the disclosure. The disclosure is defined by the category of the claims.

In addition, embodiments of the disclosure will be described with reference to cross-sectional views and/or schematic views as idealized exemplary illustrations. Therefore, the illustrations may be varied in shape depending on manufacturing techniques, tolerance, and/or etc. Further, elements in the drawings may be relatively enlarged or reduced for convenience of description. Like numerals refer to like elements throughout.

Below, the temperature control device for the semiconductor products, which changes the flow path of the test gas based on different states, according to embodiments of the disclosure will be described with reference to the accompanying drawings.

It is obvious that the up, down, left and right directions to be mentioned below may be changed in embodiments of the disclosure, and the up, down, left and right directions are merely used to complete the disclosure.

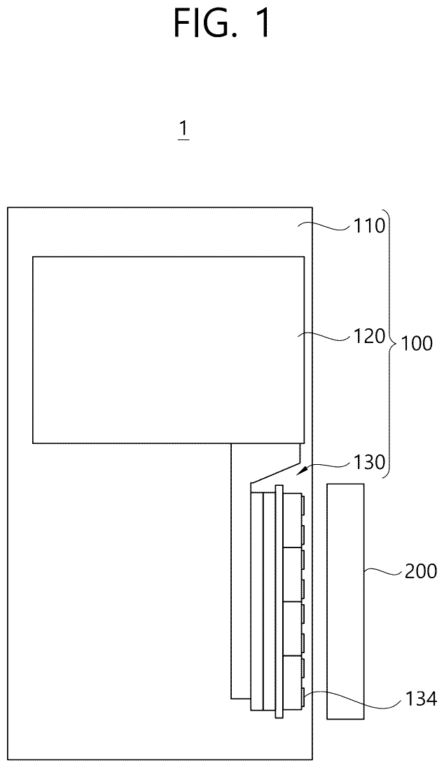

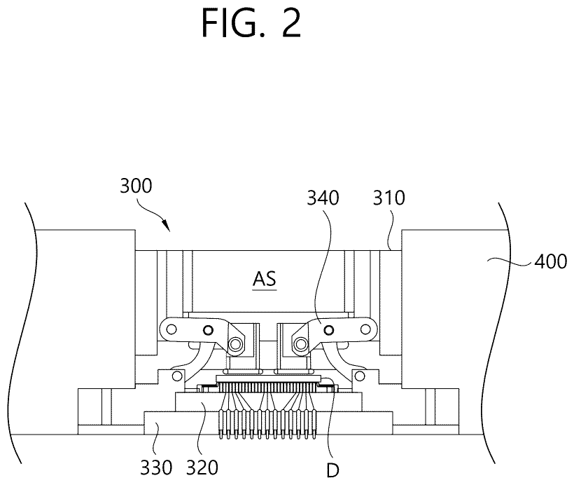

FIG. 1 is a schematic diagram showing a temperature control system according to an embodiment of the disclosure. Further, FIG. 2 is a diagram showing a test tray and an insert according to an embodiment of the disclosure. The temperature control space to be described below refers to a space where temperature is controlled for testing of semiconductor products, and an accommodating space AS (to be described later) may correspond to the temperature control space in the disclosure.

As shown in FIGS. 1 and 2, a temperature control system 1 according to an embodiment of the disclosure includes a temperature control device 100, a tester 200, an insert 300, and a test tray 400.

The temperature control device 100 may create a test environment for a semiconductor product D loaded on the insert 300. For example, the semiconductor product D undergoes a performance test while exchanging a signal with the tester 200 under high temperature, room temperature and/or low temperature conditions, and is then classified as good/defective/retest, etc. In this case, the temperature control device 100 may control a temperature atmosphere around the semiconductor product D to make the foregoing high temperature, room temperature and/or low temperature conditions. For example, the high temperature may be set in a range of 60 to 200 degrees Celsius, and the low temperature may be set in a range of 0 to minus 100 degrees Celsius. However, the temperature range may vary depending on the characteristics of the semiconductor products.

The temperature control device 100 may include a dry chamber 110, a circulation chamber 120, and a duct unit 130.

The dry chamber 110 may be configured to help maintain the internal temperature of the circulation chamber 120 at a temperature suitable for the test environment and to prevent condensation from being formed during a low temperature test. To this end, the internal temperature of the dry chamber 110 may be maintained within a predetermined range. To maintain the internal temperature of the dry chamber 110 within a predetermined range, the dry chamber 110 may include a chamber temperature control unit (not shown) that controls the internal temperature thereof constantly. The chamber temperature control unit may be provided as various conventional heat exchangers that maintain an environment inside the chamber at a constant temperature. Further, the dry chamber 110 may include a gate (not shown) allowing the duct unit 130 to enter or exit.

In more detail, the internal temperature of the dry chamber 110 may be maintained at a temperature of approximately 60 degrees Celsius or higher. This temperature condition maintains an atmosphere around the circulation chamber 120 higher than room temperature, thereby helping the circulation chamber 120 maintain a high temperature environment.

Further, the dry chamber 110 may be configured to receive dry air having a predetermined temperature, from which moisture has been removed, and exhaust the internal air to the outside, thereby keeping the internal space thereof dry and ventilated. For example, the dry chamber 110 may include a fan on one side to supply the dry air, and a ventilation hole on the other side. Accordingly, the dry chamber 110 may control humidity and/or temperature around the duct unit 130 when the internal temperature of the circulation chamber 120 is below zero temperatures, thereby preventing the condensation.

The circulation chamber 120 may be placed inside the dry chamber 110 and provide a space, in which test gas is circulated to create the test environment, around the semiconductor product D. The circulation chamber 120 allows the test gas to be circulated at a temperature controlled to be suitable for the test, thereby having an effect on shortening a test time.

The duct unit 130 may be located adjacent to one side of the test tray 400 loaded into the tester 200. The duct unit 130 may be configured to selectively spray the test gas circulating in the circulation chamber 120 toward the test tray 400. In this regard, detailed descriptions will be made later.

The push unit 134 is mounted to a distal end of the duct unit 130 facing the test tray 400, and formed with a discharge port to discharge the test gas. The push unit 134 may be provided to be relatively close to the test tray 400. For example, the push unit 134 and/or the duct unit 130 may be formed to advance toward or retreat from the tester 200, or the tester 200 may be formed to approach or move away from the push unit 134.

The tester 200 with the test tray 400 may be designed to be electrically connected to the semiconductor product D loaded onto the insert 300, and to exchange the signal for the test with the semiconductor product D. To this end, the tester 200 may include a built-in motherboard designed to transmit and receive an electric signal for the test. The tester 200 may be formed with sockets to correspond to the inserts 300 arranged on the test tray 400. When the test tray 400 is mounted to the tester 200, the semiconductor product D may be electrically connected to a test terminal of the socket. The test terminal of the socket may be implemented in various known configurations, such as a pogo pin and a conductive rubber pad.

The insert 300 may have a loading structure corresponding to the semiconductor product D, and include multiple inserts 300 mounted to the test tray 400. The loading structure corresponding to the semiconductor product D refers to a structure of loading the semiconductor product D is loaded according to the shape of the semiconductor product D, and maintaining the loaded semiconductor product D at the position corresponding to the socket of the tester 200.

The insert 300 may include an insert body 310, a contact board 320, an interface board 330, and a latch 340. The insert body 310 may refer to a frame formed to have a structure and shape to be mounted to the test tray 300, and including an accommodating space AS opened on one side so that the semiconductor product D can be loaded into the accommodating space AS. The contact board 320 may be in contact with the bottom of the semiconductor product D loaded on the insert 300. Further, the contact board 320 may be formed with a contact terminal to be in physical and electrical contact with the terminal of the loaded semiconductor product D. The interface board 330 may be placed on the back of the contact board 320 and may include a wiring pattern to be electrically connected to the contact terminal and an external terminal exposed to the outside to be electrically connected to the socket. The external terminal may have an expanded pitch compared to the contact terminal to facilitate alignment with the socket. The wiring pattern may be formed to electrically connect the external terminal and the contact terminal. The latch 340 refers to a device that maintains the position of the semiconductor product D loaded on the insert body 310, which may be implemented in various conventionally-known configurations. For example, the latch 340 may be a clamper-type member capable of holding the semiconductor product D with elastic force.

With this configuration according to an embodiment of the disclosure, the semiconductor product D is electrically connected to the socket through the insert 300 while the test tray 400 is mounted to and/or in close contact with the tester 200, thereby undergoing the test.

The test tray 400 may be formed with a groove to accommodate each insert body 310 at a position corresponding to the socket. A rough configuration of the test tray 400 has conventionally been known, and therefore detailed descriptions thereof will be omitted.

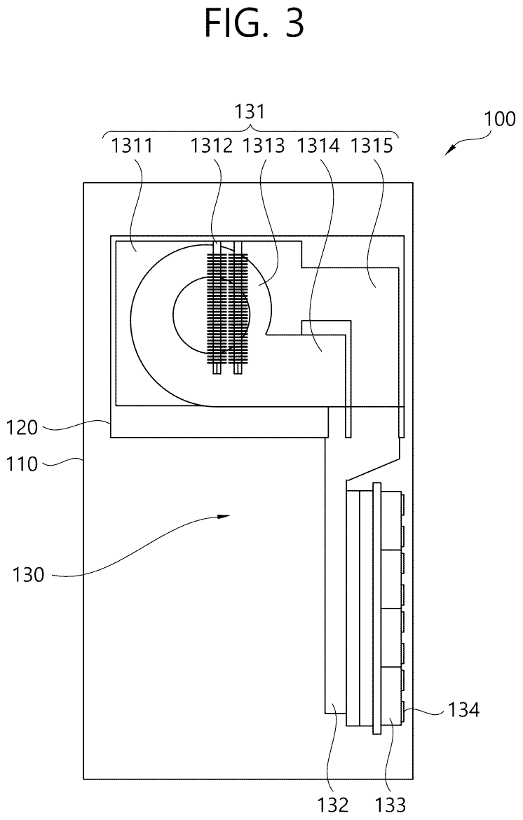

Below, the duct unit 130 according to an embodiment of the disclosure will be escribed with reference to FIG. 3. FIG. 3 is a conceptual diagram showing a temperature control device according to an embodiment of the disclosure.

As shown in FIG. 3, the duct unit 130 according to an embodiment of the disclosure may include a gas circulator 131, a distribution plate 132, and a duct block 133. The duct unit 130 may be formed to distribute and deliver the test gas supplied from the outside to the plurality of push units 134 connected to the distal end.

The gas circulator 131 may be configured to circulate the test gas and control the temperature. For example, the test gas may be temperature-controlled air or gas. The gas circulator 131 may include a circulation housing 1311, a gas temperature controller 1312, a fan 1313, a supply pipe 1314, and a return pipe 1315.

The circulation housing 1311 may be a housing located inside the circulation chamber 120 and including the built-in fan 1313. The gas temperature controller 1312 may be built in or adjacent to the circulation housing 1311 and configured to control the temperature atmosphere inside the circulation chamber 120. For example, the gas temperature controller 1312 may be provided as various conventionally-known heat exchangers. The fan 1313 may be a blowing device that circulates the test gas inside the circulation chamber 120. The supply pipe 1314 may be formed to deliver the test gas supplied from the fan 1313 to the distribution plate 132, and the return pipe 1315 may be formed to return the test gas exhausted from the distribution plate 132 into the circulation chamber 120.

The distribution plate 132 may form a circulation path for the test gas between the multiple duct blocks 133 and the gas circulator 131. The multiple duct blocks 133 may be coupled onto one side of the distribution plate 132, and distribute and deliver the test gas delivered from the gas circulator 131 to the multiple push units 134. Further, the duct block 133 may be connected to the distribution plate 132 to deliver the test gas exhausted from the connected push unit 134 back to the distribution plate 132.

The push unit 134 may be in close contact with one side of the test tray 400 or the insert 300 (see FIG. 2) in the state that the test tray 400 (see FIG. 2) is mounted to the tester 200 (see FIG. 1), thereby separating the accommodating space AS (see FIG. 2) from the external space. Further, the push unit 134 may deliver the test gas supplied from the duct block 133 to the inside of the accommodating space AS, so that the internal temperature of the accommodating space AS can be controlled.

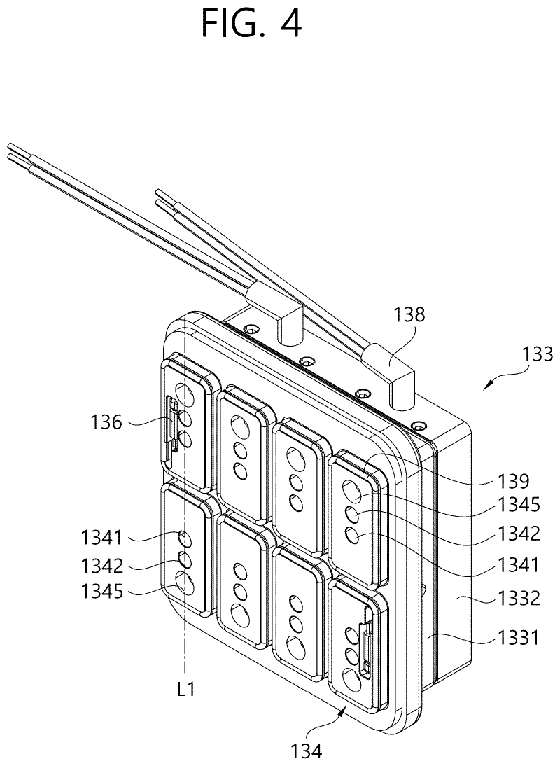

Below, the duct block 133 and the push unit 134 according to an embodiment of the disclosure will be described with reference to FIG. 4. FIG. 4 is a diagram showing a duct block and multiple push units connected to the duct block according to an embodiment of the disclosure

As shown in FIG. 4, the duct block 133 may be divided into a first duct housing 1331 and a second duct housing 1332. The first duct housing 1331 has one side to which the multiple push units 134 are mounted, so that the test gas can be distributed to the push unit 134 and returned from the push unit 134. The second duct housing 1332 has a first side connected to the first duct housing 1331 and a second side connected to the distribution plate 132 (see FIG. 3), so that the test gas can be supplied to the first duct housing 1331 and returned from the first duct housing 1331. Accordingly, the test gas supplied to the duct unit 130 may be delivered to the push unit 134 while passing through the distribution plate 132, the second duct housing 1332 and the first duct housing 1331, and discharged to the discharge port 1341. On the other hand, the test gas exhausted to the exhaust port 1342 of the push unit 134 may reach the distribution plate 132 in reverse order to the above order.

The multiple push units 134 may be connected to the distal end of the duct unit 130, and each include the discharge port 1341, the exhaust port 1342 and an auxiliary fluid discharge port 1345 formed on one side thereof. The discharge port 1341 may be a through hole for discharging the test gas to the outside, and the exhaust port 1341 may be a through hole for exhausting the test gas again. In this regard, the auxiliary fluid discharge port 1345 may be a through hole formed to discharge an auxiliary fluid. Here, the auxiliary fluid may be a fluid different in temperature from the test gas. The auxiliary fluid may be supplied to the inside of the accommodating space AS (see FIG. 2) to further cool or heat the semiconductor product facing the push unit 134. For example, the auxiliary fluid may be liquid nitrogen (LN2).

The second duct housing 1332 may connect with an auxiliary fluid supply pipe 138 so that the auxiliary fluid can be discharged to each auxiliary fluid discharge port 1345. Further, the duct unit 130 may include a valve that individually adjusts the flow rate of the flow path connected to each auxiliary fluid discharge port 1345. Thus, according to an embodiment of the disclosure, each push unit 134 among the plurality of push units 134 may discharge the auxiliary fluid independently of the other push units 134.

The discharge port 1341, the exhaust port 1342 and the auxiliary fluid discharge port 1345 may be arranged in a row along a center line L1 passing through the center point of a short side on one side of the push unit 134. In this case, FIG. 4 shows an example that the discharge port 1341 and the exhaust port 1342 are located adjacent to the center of the push unit 134, and the auxiliary fluid discharge port 1345 is located outside the exhaust port 1342, but the disclosure is not limited to these location relationships. Accordingly, the locations of the discharge port 1341, the exhaust port 1342 and the auxiliary fluid discharge port 1345 on the push unit 134 may be changed in various ways.

In this case, when the discharge port 1341 and the exhaust port 1342 are adjacent to each other, a temperature measurement sensor 136 may be placed in parallel with the discharge port 1341 and the exhaust port 1342. For example, the temperature measurement sensor 136 may be placed parallel to a virtual line L1 connecting the centers of the discharge port 1341 and the exhaust port 1342. The temperature measurement sensor 136 may be provided as various conventionally-known temperature sensors. For example, the temperature measurement sensor 136 may be a resistance temperature detector (RTD) sensor based on resistance varying depending on temperature.

To be installed in the foregoing location, the temperature measurement sensor 136 may be built in a groove recessed on one side of the push unit 134. According to the disclosure, the temperature measurement sensor 136 measures the temperature of an area adjacent to the discharge port 1341, the exhaust port 1342 and the semiconductor products in the push unit 134, thereby having an advantage of measuring the actual temperature at a location where the actual temperature of the test gas is distinguished from that affected by heat generated from the semiconductor product.

The push unit 134 may further include a packing member 139 disposed along the edge of one side thereof. The packing member 139 may seal a gap between the push unit 134 and the insert while the push unit 134 is in close contact with the test tray or the insert, thereby making sure of the sealing performance for the accommodating space. For example, the packing member 139 may be formed of sealing silicone, rubber, etc. having an approximately rectangular shape.

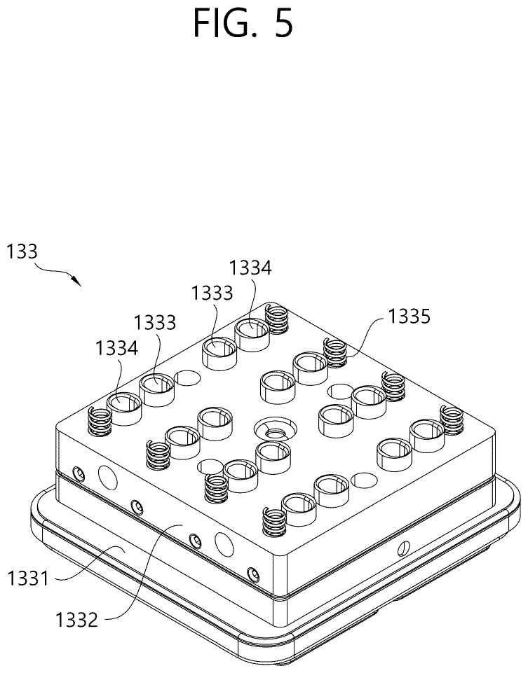

Below, the support structure of the duct block 133 according to an embodiment of the disclosure will be described with reference to FIG. 5. FIG. 5 is a diagram showing a portion of a duct block mounted to a distribution plate according to an embodiment of the disclosure.

As shown in FIG. 5, the duct block 133 according to an embodiment of the disclosure may include a plurality of duct block elastic members 1335. The plurality of duct block elastic members 1335 may elastically support the duct block 133 against the distribution plate 132 (see FIG. 3). Assuming that the push unit 134 is provided on the front of the duct block 133, the duct block elastic member 1335 may be provided on the rear of the duct block 133. For example, the duct block elastic members 1335 may be mounted to the rear of the second duct housing 1332 and protrude rearwards.

The duct block elastic members 1335 may provide elastic force to make the push units 134 (see FIG. 4) come into close contact with the test tray 400 (see FIG. 2) or the insert 300 (see FIG. 2) with uniform force, respectively. To this end, the plurality of duct block elastic members 1335 may be arranged at regular intervals on the rear of the duct block 133. For example, the plurality of duct block elastic members 1335 may be disposed coaxially with the auxiliary fluid discharge ports 1345 (see FIG. 4), respectively.

Meanwhile, a discharge channel 1333 and an exhaust channel 1334 may protrude rearwards from the second duct housing 1332. With the second duct housing 1332 mounted to the distribution plate 132, the discharge channel 1333 may receive the test gas through the distribution plate 132, and the exhaust channel 1334 may deliver the test gas to the distribution plate 132.

A through port (not shown) to which the auxiliary fluid supply pipe 138 is connected may be formed on one side of the second duct housing 1332. The auxiliary fluid flowing into the through port may be distributed in the second duct housing 1332 and/or the first duct housing 1331 and moved to each of the auxiliary fluid discharge ports 1345.

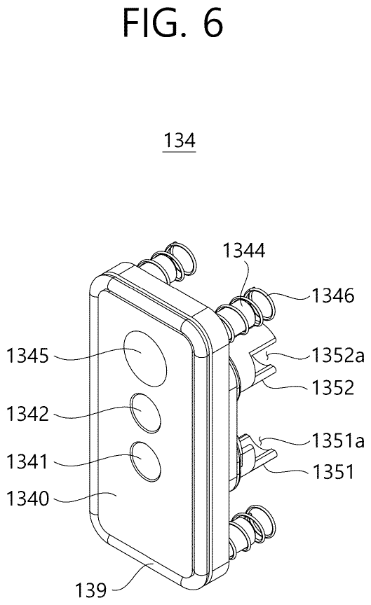

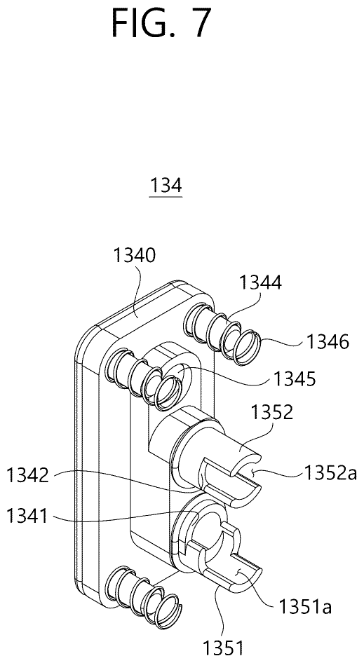

Below, the push unit according to an embodiment of the disclosure will be described with reference to FIGS. 6 and 7. FIG. 6 is a front perspective view of a push unit according to an embodiment of the disclosure. On the other hand, FIG. 7 is a rear perspective view of the push unit according to an embodiment of the disclosure.

As shown in FIGS. 6 and 7, the push unit 134 according to an embodiment of the disclosure may include a push plate 1340, push pipes 1351 and 1352, a guide end 1344, and a guide end elastic member 1346.

The push plate 1340 is approximately shaped like a rectangular plate, which is in close contact with the test tray and separates the internal space of the insert from the external space. For more reliable sealing, the packing member 139 may be provided at the edge of the push plate 1340 as described above. The discharge port 1341, the exhaust port 1342 and the auxiliary fluid discharge port 1345 may be formed penetrating the push plate 1340. The discharge port 1341, the exhaust port 1342 and the auxiliary fluid discharge port 1345 may be arranged in the central line of the push plate 1340.

The push pipes 1351 and 1352 may be tubular members protruding rearwards from the push plate 1340. The push pipes 1351 and 1352 may be inserted into the duct unit 130 (see FIG. 3). The push pipes 1351 and 1352 are divided into a discharge push pipe 1351 for fluid communication with the discharge channel 1333 (see FIG. 5) and an exhaust push pipe 1352 for fluid communication with the exhaust channel 1334 (see FIG. 5). In this case, the discharge port 1341 may have a portion formed in the push plate 1340 and the remaining portion formed in the discharge push pipe 1351. Likewise, the exhaust port 1342 may have a portion formed in the push plate 1340 and the remaining section formed in the exhaust push pipe 1352.

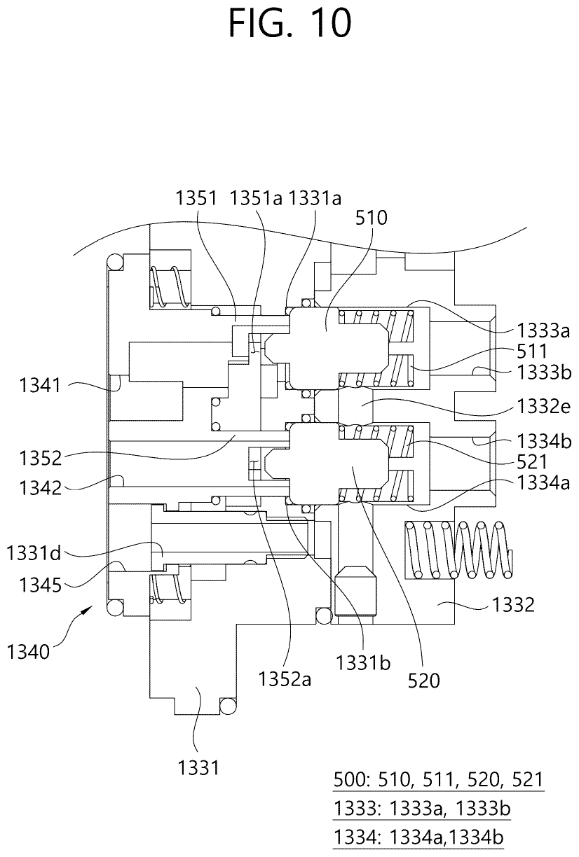

The discharge push pipe 1351 and the exhaust push pipe 1352 may be formed with gas communication grooves 1351a and 1352a. The gas communication grooves 1351a and 1352a may be formed by cutting off partial regions of the rear ends of the push pipes 1351 and 1352. Hereinafter, the gas communication groove 1351a formed in the discharge push pipe 1351 will be referred to as a discharge gas communication groove 1351a, and the gas communication groove 1352a formed in the exhaust push pipe 1352 will be referred to as an exhaust gas communication groove 1352a. The discharge gas communication groove 1351a may be formed so that the discharge port 1341 can perform fluidic communication with the outside through the rear end of the discharge push pipe 1351. Likewise, the exhaust gas communication groove 1352a may be formed so that the exhaust port 1342 can perform fluidic communication with the outside through the rear end of the exhaust push pipe 1352. In this regard, descriptions will be made later with reference to FIGS. 10 to 12.

The guide end 1344 may be an axial member to guide a moving direction of the push unit 134. The guide end 1344 may extend parallel to the push pipes 1351 and 1352 and be inserted into the duct unit 130. Further, the guide end 1344 includes a plurality of guide ends 1344 each extending rearwards from one corner of the rear side of the push plate 1340. As the moving direction of the push unit 134 according to an embodiment of the disclosure is guided by the plurality of guide ends 1344, the push unit 134 may move along the extending direction of the guide end 1344 without being biased in any direction.

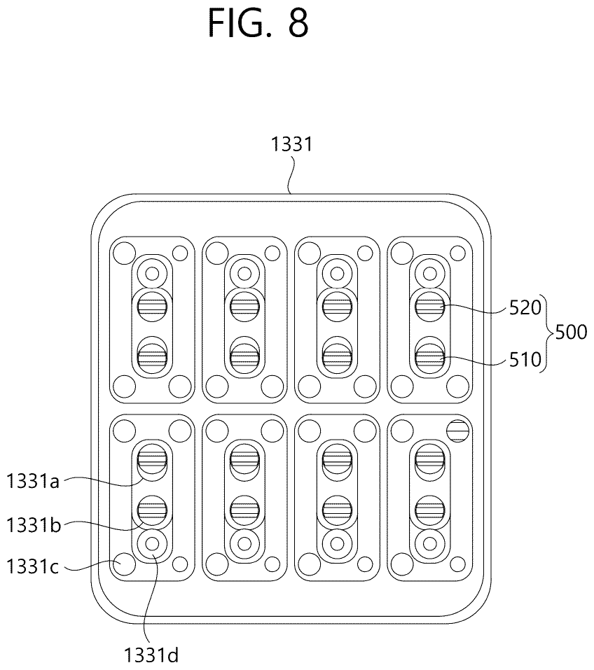

In this case, the guide end 1344 may advance and retreat as being inserted in the guide hole 1331c (see FIG. 8) formed in the duct unit 130. The plurality of guide end elastic members 1346 may be respectively placed inside the guide holes 1331c and elastically support respectively any one of the guide ends 1344. The guide end elastic member 1346 may provide elastic force to the guide end 1344 in a direction where the push pipes 1351 and 1352 come into close contact with a discharge channel push body 510 (see FIG. 8) and an exhaust channel push body 520 (see FIG. 8) to be described later.

Below, the first duct housing 1331 according to an embodiment of the disclosure will be described with reference to FIG. 8. FIG. 8 is a diagram showing a first duct housing, from which a pushing unit is separated, according to an embodiment of the disclosure.

As shown in FIG. 8, the first duct housing 1331a may be formed with a discharge communication hole 1331a, an exhaust communication hole 1331b, and a guide hole 1331c, and may be provided with an auxiliary fluid discharge pipe 1331d.

The discharge communication hole 1331a may be located between the discharge port 1341 (see FIG. 6) and the discharge channel 1333 (see FIG. 5), and may be an opening that connects them to enable fluid communication. In this manner, the exhaust communication hole 1331b may be located between the exhaust port 1342 (see FIG. 6) and the exhaust channel 1334 (see FIG. 5), and may be an opening that connects them to enable fluid communication. In an initial state, each of the discharge communication hole 1331a and the exhaust communication hole 1331b may be in close contact with the discharge channel push body 510 or the exhaust channel push body 520. In this regard, descriptions will be made later with reference to FIGS. 10 to 12. Meanwhile, the guide hole 1331c may be formed at a position corresponding to each of the guide ends 1344, and accommodate the guide end 1344.

The auxiliary fluid discharge pipe 1331d may be disposed penetrating the first duct housing 1331 and the push plate 1340. In other words, the distal end of the auxiliary fluid discharge pipe 1331d may be located inside the auxiliary fluid discharge port 1345. The auxiliary fluid discharge pipe 1331d and the auxiliary fluid supply pipe 138 may be connected for fluid communication to discharge the aforementioned auxiliary fluid into the inside of the accommodating space AS.

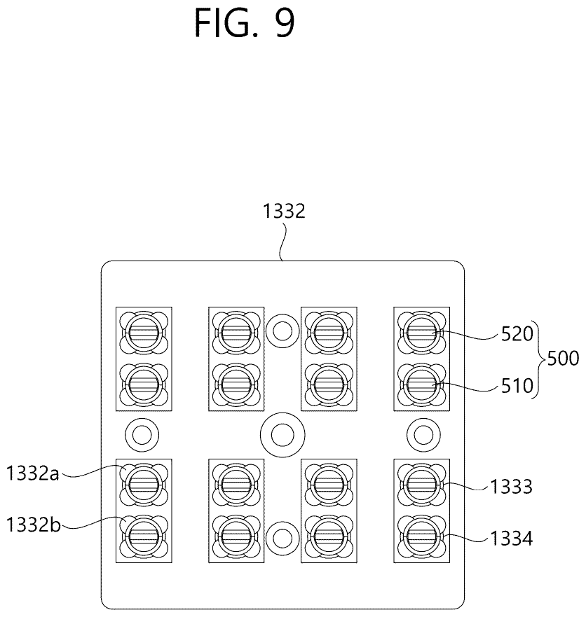

Below, the second duct housing 1332 according to an embodiment of the disclosure will be described with reference to FIG. 9. FIG. 9 is a diagram showing a second duct housing, from which a first duct housing is separated, according to an embodiment of the disclosure.

As shown in FIG. 9, the discharge channel 1333 and the exhaust channel 1334 may penetrate the second duct housing 1332 approximately vertically, and formed with expansion grooves 1332a and 1332b at the distal ends thereof. The expansion grooves 1332a and 1332b may be grooves to enlarge the distal ends of the discharge channel 1333 and the exhaust channel 1334. For example, as shown in FIG. 9, the expansion grooves 1332a and 1332b may be formed to have semicircular cross-sections, and the plurality of expansion grooves 1332a and 1332b located at regular intervals with respect to the distal ends of the discharge channel 1333 and/or the exhaust channel 1334. For the convenience of explanation, hereinafter, the expansion groove 1332a formed at the distal end of the discharge channel 1333 will be referred to as a discharge channel expansion groove 1332a, and the expansion groove 1332b formed at the distal end of the exhaust channel 1334 will be referred to as an exhaust channel expansion groove 1332b. The expansion grooves 1332a and 1332b will be described later with reference to FIGS. 10 to 12.

The temperature control device according to an embodiment of the disclosure includes a flow path opening/closing unit 500 to control the flow path of the test gas depending on the conditions.

The flow path opening/closing unit 500 obstructs the test gas flowing through the discharge communication hole 1331a in an initial state where there are no external forces, and allows the test gas to flow toward the discharge port 1341 (see FIG. 4) in a test state where the push unit 134 approaches the test tray. Likewise, the flow path opening/closing unit 500 obstructs the test gas flowing through the exhaust communication hole 1331b in the initial state, and allows the test gas passed through the exhaust port 1342 (see FIG. 4) to flow into the exhaust channel 1334 in the test state.

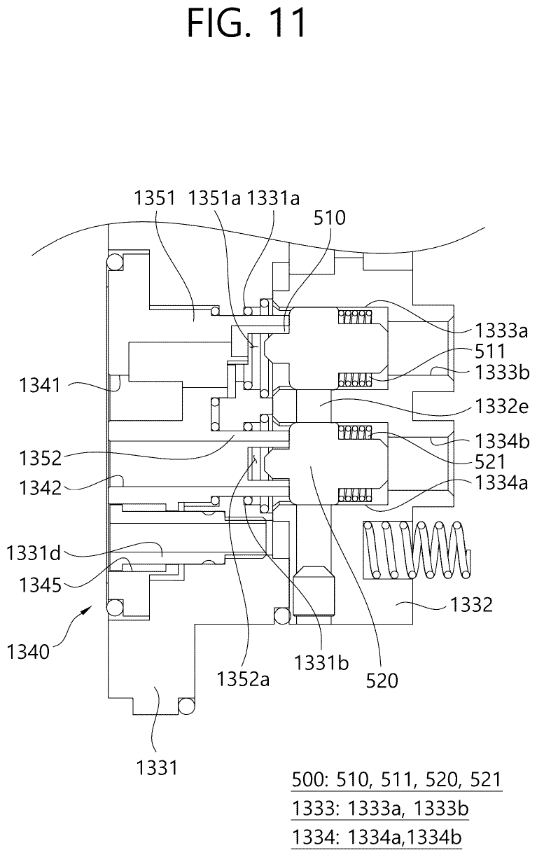

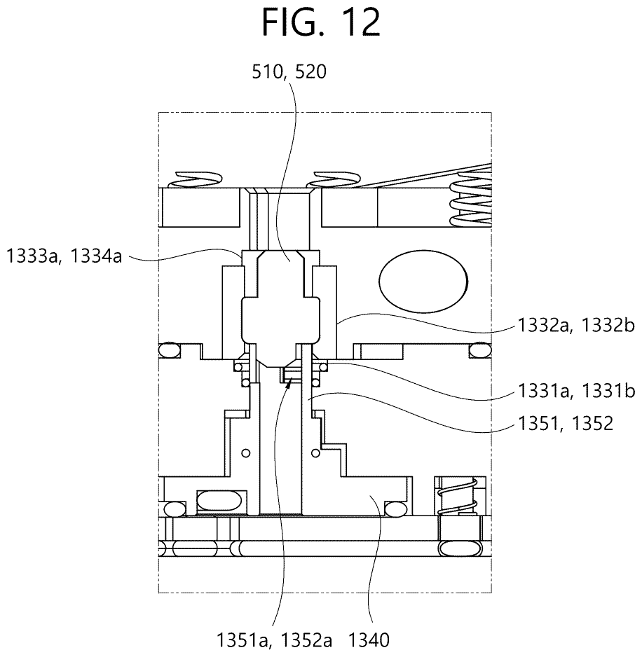

Below, a flow path control method using the flow path opening/closing unit 500 according to an embodiment of the disclosure will be described with reference to FIGS. 10 to 12. First, FIG. 10 is a diagram showing an initial state of a temperature control device according to an embodiment of the disclosure. In this regard, FIG. 11 is a diagram showing a test state of a temperature control device according to an embodiment of the disclosure. Further, FIG. 12 is a diagram for describing flow an expansion groove according to an embodiment of the disclosure.

As shown in FIG. 10, the flow path opening/closing unit 500 according to an embodiment of the disclosure may include the discharge channel push body 510, the exhaust channel push body 520, a discharge channel elastic member 511, and an exhaust channel elastic member 521. Each of the discharge channel push body 510 and the exhaust channel push body 520 may be formed to have a stepped shape of which a middle portion has a large diameter.

In more detail, the cross-section of a protruding portion of the discharge channel push body 510 may be larger than the cross-section of the discharge communication hole 1331a. Further, the cross-section of the protruding portion of the discharge channel push body 510 may be smaller than the cross-section of an accommodating section 1333a of the discharge channel 1333, which will be described later, by an allowed tolerance. Therefore, the discharge channel push body 510 may come into close contact with the discharge communication hole 1331a as being accommodated in the accommodating section 1333a, thereby closing the discharge communication hole 1331a to obstruct the flow of the test gas. On the other hand, the discharge channel push body 510 may be spaced apart from the discharge communication hole 1331a, thereby allowing the test gas to flow in the discharge communication hole 1331a through a clearance of the accommodating section 1333a of the discharge channel 1333. In this case, to ensure an appropriate flow rate of the test gas, the test gas in the accommodating section 1333a may move to the discharge communication hole 1331a through the discharge channel expansion groove 1332a extending from the outline of the discharge communication hole 1331a.

Likewise, the cross-section of a protruding portion of the exhaust channel push body 520 may be larger than the cross-section of the exhaust communication hole 1331b. Further, the cross-section of the protruding portion of the exhaust channel push body 520 may be smaller than the cross-section of an accommodating section 1334a of the exhaust channel 1334, which will be described later, by an allowed tolerance. Therefore, the exhaust channel push body 520 may come into close contact with the exhaust communication hole 1331b as being accommodated in the accommodating section 1334a, thereby closing the exhaust communication hole 1331b to obstruct the flow of the test gas. On the other hand, the exhaust channel push body 520 may be spaced apart from the exhaust communication hole 1331b, thereby allowing the test gas to pass through the exhaust communication hole 1331b and move to the accommodating section 1334a of the exhaust channel 1334. In this case, to ensure an appropriate flow rate of the test gas, the test gas may pass through the exhaust communication hole 1331b and move to the accommodating section 1334a through the exhaust channel expansion groove 1332b extending from the outline of the exhaust communication hole 1331b.

In the foregoing embodiment, the test gas is discharged to the discharge port 1341 via the discharge channel 1333, the discharge channel expansion groove 1332a and the discharge communication hole 1331a, and is exhausted to the exhaust channel 1334 via the exhaust port 1342, the exhaust communication hole 1331b, and the exhaust channel expansion groove 1332b. However, the disclosure is not necessarily limited to the foregoing embodiment. For example, the push pipes 1351 and 1352 may pass through the discharge communication hole 1331a and the exhaust communication hole 1331b and be then inserted into the discharge channel 1333 and the exhaust channel 1334 up to an internal location. In this case, the test gas may be discharged as flowing into the gas communication groove 1351a after passing through the discharge channel 1333 and the discharge channel expansion groove 1332a. In addition, the test gas may be exhausted to the exhaust channel 1334 as flowing into the exhaust channel expansion groove 1332b through the gas communication groove 1352a.

Meanwhile, the discharge channel elastic member 511 and the exhaust channel elastic member 521 may be formed to elastically support the discharge channel push body 510 and the exhaust channel push body 520, respectively. For example, the discharge channel elastic member 511 and/or the exhaust channel elastic member 521 may be provided as a helical spring or as a member capable of replacing the helical spring. The discharge channel elastic member 511 may provide a restoring force in a direction where the discharge channel push body 510 comes into close contact with the discharge communication hole 1331a. Likewise, the exhaust channel elastic member 521 may provide a restoring force in a direction where the exhaust channel push body 520 comes into close contact with the exhaust communication hole 1331b.

According to an embodiment of the disclosure, the discharge channel 1333 may include the accommodating section 1333a and an inner section 1333b. Similarly, the exhaust channel 1334 according to an embodiment of the disclosure may include the accommodation section 1334a and an inner section 1334b. For distinguishment, the accommodating section 1333a and the inner section 1333b formed in the discharge channel 1333 will be referred to as a discharge channel accommodating section 1333a and a discharge channel inner section 1333b, respectively. Similarly, the accommodating section 1334a and the inner section 1334b formed in the exhaust channel 1334 will be referred to as an exhaust channel accommodating section 1334a and an exhaust channel inner section 1334b, respectively.

The discharge channel accommodating section 1333a may have a first end connected to the discharge communication hole 1331a, and a second end connected to the discharge channel inner section 1333b, and accommodate the discharge channel push body 510 therein. The discharge channel push body 510 may advance and retreat within the discharge channel accommodating section 1333a based on the external force and the elastic force of the discharge channel elastic member 511. The test gas supplied from the outside may pass through the discharge channel inner section 1333b and reach the discharge channel accommodating section 1333a. For example, the test gas supplied to the discharge channel 1333 may be the test gas inside the circulation chamber 120 (see FIG. 1) described above.

Meanwhile, a stepped portion supporting the discharge channel elastic member 511 may be formed on the rear end of the discharge channel accommodating section 1333a, based on difference in inner diameter between the discharge channel inner section 1333b and the discharge channel accommodating section 1333a. Here, the stepped portion may refer to a portion protruding inward in the channel based on the difference in inner diameter. For example, the discharge channel inner section 1333b may be formed to have a smaller inner diameter than the discharge channel accommodating section 1333a so that the discharge channel 1333 can have a stepped cross-section. The discharge channel elastic member 511 may be located between the discharge channel push body 510 and the stepped portion formed by difference in width between the discharge channel accommodating section 1333a and the discharge channel inner section 1333b.

Similarly, the exhaust channel accommodating section 1334a may have a first end connected to the exhaust communication hole 1331b, and a second end connected to the exhaust channel inner section 1334b, and accommodate the exhaust channel push body 520 therein. The exhaust channel push body 520 may advance and retreat within the exhaust channel accommodating section 1334a based on the external force and the elastic force of the exhaust channel elastic member 521. The test gas inside the accommodating space AS (see FIG. 2) may pass through the exhaust communication hole 1331b and be exhausted to the outside through the exhaust channel 1334. For example, the destination of the test gas exhausted to the exhaust channel 1334 may be the circulation chamber 120 described above.

A stepped portion supporting the exhaust channel elastic member 521 may be formed on the rear end of the exhaust channel accommodating section 1334a, based on difference in inner diameter between the exhaust channel inner section 1334b and the exhaust channel accommodating section 1334a. Here, the stepped portion may refer to a portion protruding inward in the channel based on the difference in inner diameter. For example, the exhaust channel inner section 1334b may be formed to have a smaller inner diameter than the exhaust channel accommodating section 1334a so that the exhaust channel 1334 can have a stepped cross-section. The exhaust channel elastic member 521 may be located between the exhaust channel push body 520 and the stepped portion formed by difference in width between the exhaust channel accommodating section 1334a and the exhaust channel inner section 1334b.

Meanwhile, the second duct housing 1332 may be formed with a circulation channel 1332e connecting the discharge channel accommodating section 1333a and the exhaust channel accommodating section 1334a.

The circulation channel 1332e may not be obstructed by the discharge channel push body 510 and/or the exhaust channel push body 520 in the initial state, and both ends thereof may be obstructed by the discharge channel push body 510 and/or the exhaust channel push body 520 in the test state. Specifically, in the initial state, the circulation channel 1332e may be exposed to one side of the discharge channel push body 510 and/or the exhaust channel push body 520. Further, in the test state, the circulation channel 1332e may have a first end facing the discharge channel push body 510 and a second end facing the exhaust channel push body 520.

Below, the flow of the test gas in the initial state according to an embodiment of the disclosure will be described with reference to FIG. 10.

In the initial state, the discharge push pipe 1351 and the exhaust push pipe 1352 may be in close contact with the discharge channel push body 510 and the exhaust channel push body 520by the guide end elastic member 1346 (see FIG. 7), respectively. In this case, to prevent the discharge push pipe 1351 and the exhaust push pipe 1352 from pushing the discharge channel push body 510 and the exhaust channel push body 520 and entering the areas of the discharge channel 1333 or the exhaust channel 1334, the elastic forces of the discharge channel elastic member 511 and the exhaust channel elastic member 521 may be stronger than that of the guide end elastic member 1346.

Meanwhile, a portion expanded radially from the distal end of the auxiliary fluid discharge pipe 1331d (i.e., the end facing an external space) and an inner wall of the push plate 1340 forming the auxiliary fluid discharge port 1345 are used as a kind of stopper, thereby preventing the push plate 1340 from being separated from the first duct housing 1331. In more detail, the auxiliary fluid discharge port 1345 is formed to have an outlet portion diameter corresponding to a distal end diameter of the auxiliary fluid discharge pipe 1331d, and an opposite portion diameter smaller than the distal end diameter of the auxiliary fluid discharge pipe 1331d. Therefore, the push plate 1340 is prevented from advancing further than the distal end of the auxiliary fluid discharge pipe 1331d and from being separated from the first duct housing 1331.

In this state, the discharge channel push body 510 and the exhaust channel push body 520 advance as much as possible, thereby preventing gas from flowing through the discharge communication hole 1331a and the exhaust communication hole 1331b. Therefore, the test gas supplied to the discharge channel 1333 is not discharged to the outside but returned to the circulation chamber 120 through the exhaust channel 1334 via the circulation channel 1332e. Accordingly, in the initial state, the test gas is continuously circulated between the circulation chamber 120 and the push plate 1340, thereby controlling the temperature.

In this case, according to an embodiment of the disclosure, a plurality of O-rings may be provided to seal minute gaps between the members. For example, in the initial state, the O-ring may be disposed to seal the minute gaps between the push bodies 510 and 520 and the communication ports 1331a and 1331b and between the push pipes 1351 and 1352 and the first duct housing 1331.

Below, the flow of the test gas in the test state according to an embodiment of the disclosure will be described with reference to FIG. 11.

In the test state, the push plate 1340 may be in close contact with the test tray, the insert and/or the semiconductor product. In this case, the push plate 1340 may be in close contact with the test tray or the insert when it is necessary to minimize contact and vibration with a target semiconductor product because that semiconductor product is fine and sophisticated. For example, the semiconductor products in this case may include an HBM, a HBM die, etc. As another example, the push plate 1340 may be in direct contact with the semiconductor product when it directly presses and exchanges high with the semiconductor product. For example, the semiconductor products in this case may include memory modules.

The push plate 1340 pressed by the force based on close contact with the test tray, the insert and/or the semiconductor product may be accommodated in the first duct housing 1331. Thus, the discharge push pipe 1351 may press the discharge channel push body 510 into the accommodating section 1333a. Likewise, the exhaust push pipe 1352 may press the exhaust channel push body 520 into the accommodating section 1334a. Therefore, in the process of switching over from the initial state to the test state, the distal end portions of the discharge push pipe 1351 and the exhaust push pipe 1352 may be inserted into the discharge channel 1333 or the exhaust channel 1334 while passing through the discharge communication hole 1331a and the exhaust communication hole 1331b, respectively.

In this state, the discharge gas communication groove 1351a and the exhaust gas communication groove 1352a may be located in the discharge channel accommodating section 1333a (or the discharge communication hole 1331a) and the exhaust channel accommodating section 1334a (or the exhaust communication hole 1331b), respectively. More specifically, in this state, at least a portion of the discharge gas communication groove 1351a may be located in the inner space of the discharge channel expansion groove 1332a. Likewise, in this state, at least a portion of the exhaust gas communication groove 1352a may be located in the inner space of the exhaust channel expansion groove 1332b.

Thus, the test gas inside the discharge channel accommodating section 1333a may flow to the discharge port 1341 through the discharge channel expansion groove 1332a and the discharge gas communication groove 1351a, and be finally discharged to the outside. Likewise, the test gas flowing into the exhaust port 1342 may flows into the exhaust channel accommodating section 1333b through the exhaust gas communication groove 1352a and the exhaust channel expansion groove 1332b, and be finally delivered to the circulation chamber 120.

In this case, both ends of the circulation channel 1332e are obstructed by the discharge channel push body 510 and the exhaust channel push body 520, and therefore there may be no or negligible flow rates of the test gas flowing in the circulation channel 1331e.

Meanwhile, the temperature control device according to an embodiment of the disclosure with the discharge channel expansion groove 1332a and the exhaust channel expansion groove 1332b may have the following effects. First, the discharge channel expansion groove 1332a may diffuse the test gas flowing in a narrow gap between the discharge channel push body 510 and the inner wall of the discharge channel 1333 into a wider space, thereby lowering the speed of the gas discharged through the discharge port 1341. Therefore, the test gas may be evenly diffused rather than being sprayed intensively at a certain point inside the accommodating space AS. Meanwhile, the exhaust channel expansion groove 1332a may enlarge the exhaust port through which the test gas is exhausted, thereby preventing the test gas from being exhausted not smoothly while forming a vortex when being exhausted through a narrow gap.

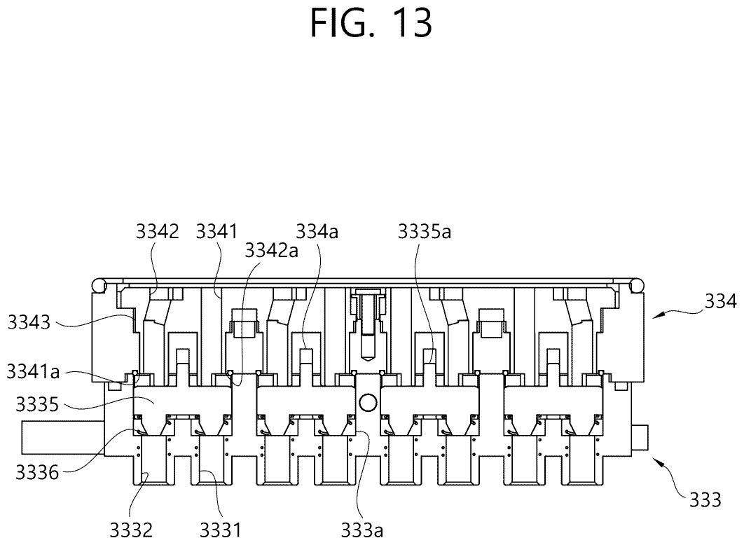

Below, the structures of the duct block and the push unit according to another embodiment of the disclosure will be described with reference to FIG. 13. FIG. 13 is a schematic cross-sectional view of a duct block and a push unit according to another embodiment of the disclosure. Hereinafter, descriptions will be made on the assumption that the duct block 333 is located below the push unit 334. To avoid redundant descriptions, descriptions about the same or similar parts to those of the foregoing embodiment will be omitted, and differences will be described intensively.

As shown in FIG. 13, according to another embodiment of the disclosure, one push unit 334 may be formed to correspond to a plurality of inserts 300 (see FIG. 2). The push unit 334 may be formed with a discharge port 3341 and an exhaust port 3342, which form a pair corresponding to one insert 300. In this case, FIG. 13 shows the discharge port 3341 is located to the right of the exhaust port 3342, but may also be located to the left of the exhaust port 3342. Meanwhile, similarly to the foregoing embodiment, the discharge port 3341 and the exhaust port 3342 may extend along the central axis of a push pipe 3343 protruding from the push unit 334 in one direction. Further, similarly to the foregoing embodiment, the discharge communication hole 3341a and the exhaust communication hole 3342a may be formed penetrating portions of the duck block 333, in which the push pipes 3343 are inserted.

A key feature of the temperature control device according to the embodiment shown in FIG. 13 is that the circulation path of the test gas is controllable with a single push body 3335. In other words, the single push body 3335 in this embodiment may replace the roles of the discharge channel push body 510 and the exhaust channel push body 520 used in the previous embodiment.

In this embodiment, flow path opening/closing units 3335 and 3336 may be formed to include one push body 3335 and at least one push body elastic member 3336. More specifically, according to this embodiment, the push body 3335 may be placed in the push body accommodating groove 333a recessed from the top of the duct block 334. The push body accommodating groove 333a may be connected to each of a discharge channel 3331 and an exhaust channel 3332 through openings formed on the bottom thereof. Further, a discharge communication hole 3341a and an exhaust communication hole 3342a may be formed penetrating the top of the push body accommodating groove 333a. Meanwhile, the push body elastic member 3336 may be located between the push body 3335 and the inner wall of the duct block 333 within the push body accommodating groove 333a, and may be provided equally or similarly to the discharge channel elastic member 511 and/or the exhaust channel elastic member 521 of the previous embodiment.

In the state that the duct block 333 and the push unit 334 are coupled, the push pipe 3343 of the push unit 334 is accommodated in the push body accommodating groove 333a, and the distal end may be in close contact with the push body 3335. Similarly to the foregoing embodiment, even in this embodiment, the gas communication grooves 1351a and 1352a (see FIG. 6) may be formed in the push pipe 3343. Therefore, like the foregoing embodiment, the discharge port 3341 and the exhaust port 3342 may perform fluidic communication with the space inside the push body accommodating groove 333a through the gas communication grooves 1351a and 1352a (see FIG. 6). Further, although not shown, similarly to the foregoing embodiment, even in this embodiment, expansion grooves 1332a and 1332b (see FIG. 12) may be formed extending from the discharge communication hole 3341a and the exhaust communication hole 3342a. Like the foregoing embodiment, the expansion groove may be a groove formed to facilitate fluidic communication based on the gas communication groove when the push pipe 3343 is fully accommodated in the push body accommodating groove 333a.

In the state that there are no external forces, the push body 3335 according to the embodiment shown in FIG. 13 may be in close contact with the top of the push body accommodating groove 333a. Thus, the discharge communication hole 3341a and the exhaust communication hole 3342a are in close contact with the top of the push body 3335, and the internal space of the push body accommodating groove 333a may be isolated from the external space. To this end, the push body elastic member 3336 may elastically support the push body 3335 in the direction of the push unit 334. In this state, the test gas discharged through the discharge channel 3331 may not be discharged to the outside as blocked by the push body 3335, but be directly exhausted to the exhaust channel 3332 as moved through a spare space of the push body accommodating groove 333a or through a separate circulation channel 1332e (see FIG. 10).

On the other hand, when the push unit 334 or the duct block 333 is pressed by an external force, the push unit 334 may be accommodated inside the duct block 333 as much as possible while overcoming the elastic force of the push body elastic member 3336 as shown in FIG. 13. In this state, the test gas discharged to a discharge channel 3331 may sequentially pass through the expansion groove formed in the push body accommodating groove 333a and the gas communication groove of the push pipe 3343, and be finally discharged to the discharge port 3341. Similarly, the test gas exhausted to the exhaust port 3342 may pass through the exhaust port 3342, then pass through the gas communication groove and expansion groove in sequence, and be finally exhausted to the outside through an exhaust channel 3332.

In this case, the external force that moves the push body 3335 may be obtained as the push unit 334 is pressed by the test tray, may be obtained through a separate member that rises as the test tray approaches, or may be obtained by a separate driving device.

Meanwhile, according to the embodiment shown in FIG. 13, the push body 3335 may be formed with an alignment protruding end 3335a protruding from the surface thereof facing the push unit 334. The alignment protruding end 3335a may be inserted into an alignment groove 334a formed between the discharge port 3341 and the exhaust port 3342 of the push unit 334. The alignment protruding end 3335a and the align groove 334a may extend in a direction parallel to an approaching direction of the test tray relative to the push unit 334, and guide a moving direction of when the push unit 334 and the duct block 333 come into close contact with each other. Thus, according to an embodiment of the disclosure, even though the push unit 334 and the duct block 333 are slightly misaligned from the initial state due to thermal deformation, the push unit 334 is moved in a right direction to the duct block 333.

According to the embodiment shown in FIG. 13, the fluid flow paths for both the discharge channel 3331 and the exhaust channel 3332 are controlled by the single push body 3335, and it is thus in particular advantageous for a small semiconductor product having a very narrow gap between the discharge channel 3331 and the exhaust channel 3332.

According to the embodiments of the disclosure, the effects are at least as follows.

A test environment is prepared in advance to shorten a test preparation time. Further, heat exchange with the outside is minimized in a preparation state, thereby maximizing an energy efficiency.

The effects of the disclosure are not limited to those described above, and various other effects are included in the foregoing description

A person having ordinary knowledge in the art to which the disclosure pertains may understood that the disclosure may be embodied in other specific forms without changing technical spirit or essential features. Accordingly, the embodiments described above are illustrative and not restrictive in all aspects. The scope of the disclosure is defined by the appended claims rather than the foregoing detailed description, and all changes or modifications derived from the meaning and scope of the appended claims and their equivalents are construed as falling within the scope of the disclosure.

*Reference Numerals

| | |
|---|---|
| 1: temperature control system | |
| 100: temperature control device | |
| 110: dry chamber | |
| 120: circulation chamber | |
| 130: duct unit | |
| 131: gas circulator | |
| 1311: circulation housing | |
| 1312: gas temperature controller | |
| 1313: fan | |
| 1314: supply pipe | 1315: return pipe |
| 132: distribution plate | 133, 333: duct block |
| 1331: first duct housing | |
| 1331a: discharge communication hole | |
| 1331b: exhaust communication hole | |
| 1331c: guide hole | |
| 1331d: auxiliary fluid discharge pipe | |
| 1332: second duct housing | |
| 1332a: discharge channel expansion groove | |
| 1332b: exhaust channel expansion groove | |
| 1333, 3331: discharge channel | |
| 1334, 3332: exhaust channel | |
| 1335: duct block elastic member | |
| 134, 334: push unit | 1340: push plate |
| 1341, 3341: discharge port | |
| 1342, 3342: exhaust port | 1344: guide end |
| 1345: auxiliary fluid discharge port | |
| 1346: guide end elastic member | |
| 1351, 1352: push pipe | |
| 1351a, 1352a: gas communication groove | |
| 138: auxiliary fluid supply pipe | |
| 139: packing member | |
| 200: tester | 300: insert |
| 310: insert body | 320: contact board |
| 330: interface board | 340: latch |
| 400: test tray | |
| 500: flow path opening/closing unit | |
| 510: discharge channel push body | |
| 511: discharge channel elastic member | |
| 520: exhaust channel push body | |
| 521: exhaust channel elastic member | |
| AS: accommodating space | |

What is claimed is:

1. A temperature control device for a semiconductor product, which changes a flow path of test gas based on different states, comprising:
a push unit provided to relatively approach a test tray for carrying the semiconductor product, and formed a discharge port to discharge the test gas for controlling a test environment;
a duct unit that comprising a discharge channel formed to deliver the test gas from an outside to the discharge port; and
a flow path opening/closing unit configured to prevent the test gas from being discharged to the discharge port by obstructing the test gas flowing through a discharge communication hole located between the discharge port and the discharge channel in an initial state, and to allow the test gas to be discharged to the discharge port in a test state where the push unit relatively approaches the test tray.

2. The temperature control device of claim 1, wherein the flow path opening/closing unit comprises a discharge channel push body placed inside the discharge channel, configured to be in close contact with the discharge communication hole in the initial state, and to be spaced apart from the discharge communication hole in the test state switched by receiving an external force.

3. The temperature control device of claim 2, wherein the flow path opening/closing unit further comprises a discharge channel elastic member configured to provide a restoring force to bring the discharge channel push body into close contact with the discharge communication hole.

4. The temperature control device of claim 3, wherein the discharge channel comprises an accommodating section having one end connected to the discharge communication hole and allowing the discharge channel push body to advance and retreat therein, and an inner section connected to other end of the accommodating section and forming a stepped portion to support the discharge channel elastic member.

5. The temperature control device of claim 2, wherein the duct unit further comprises an exhaust channel formed to exhaust the test gas, and a circulation channel connecting the discharge channel and the exhaust channel.

6. The temperature control device of claim 5, wherein the push unit further comprises an exhaust port to perform fluidic communication with the exhaust channel.

7. The temperature control device of claim 6, wherein the flow path opening/closing unit further comprises an exhaust channel push body placed inside the exhaust channel, configured to be in close contact with an exhaust communication hole located between the exhaust port and the exhaust channel in the initial state, and to be spaced apart from the exhaust communication hole in the test state.

8. The temperature control device of claim 4, wherein the circulation channel is exposed to one side of the discharge channel push body in the initial state, and faces the discharge channel push body in the test state.

9. The temperature control device of claim 2, wherein the push unit comprises a push pipe configured to form at least a partial section of the discharge port, to be inserted into the duct unit, and to press the discharge channel push body as switched over from the initial state to the test state.

10. The temperature control device of claim 9, wherein the push pipe comprises a gas communication groove formed at a distal end thereof to communicate with the discharge port so that the test gas in the discharge channel can be delivered to the discharge port in the test state.

11. The temperature control device of claim 10, wherein the discharge channel push body is formed to have a cross-section larger than the cross-section of the discharge communication hole and smaller than the cross-section of the discharge channel.

12. The temperature control device of claim 9, wherein the push unit further comprises a guide end extending parallel to the push pipe and inserted in the duct unit to guide a moving direction of the push unit.

13. The temperature control device of claim 12, wherein the push unit further comprises a guide end elastic member configured to elastically support the guide end in a direction of bring the push pipe into close contact with the discharge channel push body.

14. The temperature control device of claim 1, wherein the duct unit comprises an auxiliary fluid discharge pipe disposed penetrating the push unit, and allowing an auxiliary fluid different in temperature from the test gas to flow therein.

15. The temperature control device of claim 1, further comprising a temperature measurement sensor adjacent to the discharge port and an exhaust port, and disposed parallel to a virtual line connecting the discharge port and the exhaust port.
